(19) United States
(12) Patent Application Publication
(10) Pub. No.: US 2024/0349455 A1
(43) Pub. Date: Oct. 17, 2024

(54) PHASE CHANGE HEATSINK, MANUFACTURING PROCESS THEREOF, AND COMMUNICATION DEVICE HAVING THE HEATSINK

(71) Applicant: Telefonaktiebolaget LM Ericsson (publ), Stockholm (SE)

(72) Inventors: Haijiang WANG, Beijing (CN); Shuaijun LI, Beijing (CN)

(73) Assignee: Telefonaktiebolaget LM Ericsson (publ), Stockholm (SE)

(21) Appl. No.: 18/683,049

(22) PCT Filed: Jul. 29, 2022
(86) PCT No.: PCT/CN2022/108944

§ 371 Date: Feb. 12, 2024

(30) Foreign Application Priority Data
Aug. 13, 2021 (WO) PCT/CN2021/112560

(51) Int. Cl. H05K 7/20

(52) U.S. Cl. CPC H05K 7/2039

(57) ABSTRACT

A phase change heatsink, a process for manufacturing the heatsink, and a communication device having the heatsink are disclosed. The phase change heatsink includes a heatsink base and a phase change heat spreader integrated into the heatsink base. The phase change heat spreader includes a cover attached to the heatsink base and defines an enclosed cavity, in which one or more support pillars are provided in the enclosed cavity to extend from the heatsink base to the cover, and which is partially filled with refrigerant. The process comprises steps of: a) die-casting the heatsink base to shape the cavity and the support pillars; b) attaching the cover to the heatsink base to enclose the cavity; and c) filling a certain amount of refrigerant into the cavity through a filling port, and scaling the filling port. The attaching step b) further comprises a step b1) of sealing a periphery of the cover to the heatsink base, and a step b2) of bonding a central portion of the cover to the support pillars.

### TECHNICAL FIELD

The present disclosure generally relates to components of communication device, and more particularly, to a phase change heatsink for dissipating heat from heat sources, a process for manufacturing the phase change heatsink, and a communication device having the phase change heatsink.

### BACKGROUND

This section introduces aspects that may facilitate better understanding of the present disclosure. Accordingly, the statements of this section are to be read in this light and are not to be understood as admissions about what is in the prior art or what is not in the prior art.

Components with high heat flux, such as power amplifiers and digital chips, are always thermal design bottleneck for communication product. To cool such components, aluminum heatsink for natural convection cooling is widely used. The thermal conductivity of traditional aluminum heatsink is not high, which results in high heat spreading resistance on heatsink base, and the whole heatsink cooling efficiency will become lower.

Compared with traditional aluminum heatsink, phase change heat transfer is a high-efficiency heat transfer way. This technology can obviously improve the heat transfer of heatsink and help to dissipate more heat compared with aluminum heatsink based on the same heatsink dimension. Heat pipe and vapor chamber are mature solutions which use phase change heat transfer technology, and are applied as separate loose parts mounted on the heatsink base to improve heat spreading on the heatsink base.

The heat pipe can only improve one-dimensional heat transfer along its length, but can't improve two-dimensional heat transfer in a plane direction. Thus, the heat pipe is not a good solution to reduce the heat spreading resistance. The vapor chamber is targeted to improve the two-dimensional heat transfer in a plane direction. However, the vapor chamber can't be manufactured with a large dimension, and its manufacturing cost is quite high. Further, since vapor chamber shell is made of copper material, it will also add extra certain weight to the product. In addition, the heat pipe or vapor chamber is manufactured separately and then is assembled with the heatsink base together. There is extra thermal resistance on contact surface between the heat pipe or vapor chamber and the heatsink base.

### SUMMARY

This summary is provided to introduce a selection of concepts in a simplified form that are further described below in the detailed description. This summary is not intended to identify key features or essential features of the claimed subject matter, nor is it intended to be used to limit the scope of the claimed subject matter.

One of the objects of the disclosure is to provide a phase change heatsink, which can significantly reduce the heat spreading resistance so as to improve the heat spreading on the heatsink, and which can be easily manufactured with lower cost.

According to a first aspect of the disclosure, there is provided a phase change heatsink. The phase change heatsink includes a heatsink base and a phase change heat spreader integrated into the heatsink base. The phase change heat spreader includes a cover attached to the heatsink base and defines an enclosed cavity. One or more support pillars are provided in the enclosed cavity to extend from the heatsink base to the cover. The enclosed cavity is partially filled with refrigerant.

According to a second aspect of the disclosure, there is provided a process for manufacturing the above phase change heatsink. The process comprises steps of: a) die-casting the heatsink base to shape the cavity and the support pillars; b) attaching the cover to the heatsink base to enclose the cavity; and c) filling a certain amount of refrigerant into the cavity through a filling port, and sealing the filling port. The attaching step b) further comprises a step b1) of sealing a periphery of the cover to the heatsink base, and a step b2) of bonding a central portion of the cover to the support pillars.

In an embodiment of the disclosure, the sealing step b1) is performed by laser welding or friction stir welding.

In an embodiment of the disclosure, the bonding step b2) is performed by laser welding or glue bonding.

In an embodiment of the disclosure, the heatsink base and the cover are each made of aluminum material.

In an embodiment of the disclosure, the filling port is formed at a side of the heatsink base.

In an embodiment of the disclosure, two or more cavities are shaped in the die-casting step a).

In an embodiment of the disclosure, in the die-casting step a), a plurality of hentsink fins are shaped integrally with the heatsink base at an opposite side of the cavity.

In an embodiment of the disclosure, the heatsink base includes a stepped structure against which the periphery of the cover bears before the attaching step b) is performed.

According to a third aspect of the disclosure, there is provided a communication device. The communication device includes at least one heat source and a phase change heatsink according to the first aspect of the disclosure, wherein the phase change heatsink is vertically mounted such that a lower portion of the phase change heat spreader corresponds to the at least one heat source.

### BRIEF DESCRIPTION OF THE DRAWINGS

These and other objects, features and advantages of the disclosure will become apparent from the following detailed description of illustrative embodiments thereof, which are to be read in connection with the accompanying drawings.

FIG. 1 is a view schematically illustrating a phase change heatsink according to an embodiment of the disclosure;

FIG. 2 illustrates steps for manufacturing the phase change heatsink according to the embodiment; and

FIG. 3 is a schematic diagram illustrating a phase change heat transfer process inside the phase change heatsink according to the embodiment.

### DETAILED DESCRIPTION

The embodiments of the present disclosure are described in detail with reference to the accompanying drawings. It should be understood that these embodiments are discussed only for the purpose of enabling those skilled in the art to better understand and thus implement the present disclosure, rather than suggesting any limitations on the scope of the present disclosure. Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Furthermore, the described features, advantages, and characteristics of the disclosure may be combined in any suitable manner in one or more embodiments. Those skilled in the relevant art will recognize that the disclosure may be practiced without one or more of the specific features or advantages of a particular embodiment. In other instances, additional features and advantages may be recognized in certain embodiments that may not be present in all embodiments of the disclosure.

Generally, all terms used herein are to be interpreted according to their ordinary meaning in the relevant technical field, unless a different meaning is clearly given and/or is implied from the context in which it is used. All references to a/an/the element, apparatus, component, means, step, etc. are to be interpreted openly as referring to at least one instance of the element, apparatus, component, means, step, etc., unless explicitly stated otherwise. Any feature of any of the embodiments disclosed herein may be applied to any other embodiment, wherever appropriate. Likewise, any advantage of any of the embodiments may apply to any other embodiments, and vice versa. Other objectives, features and advantages of the enclosed embodiments will be apparent from the following description.

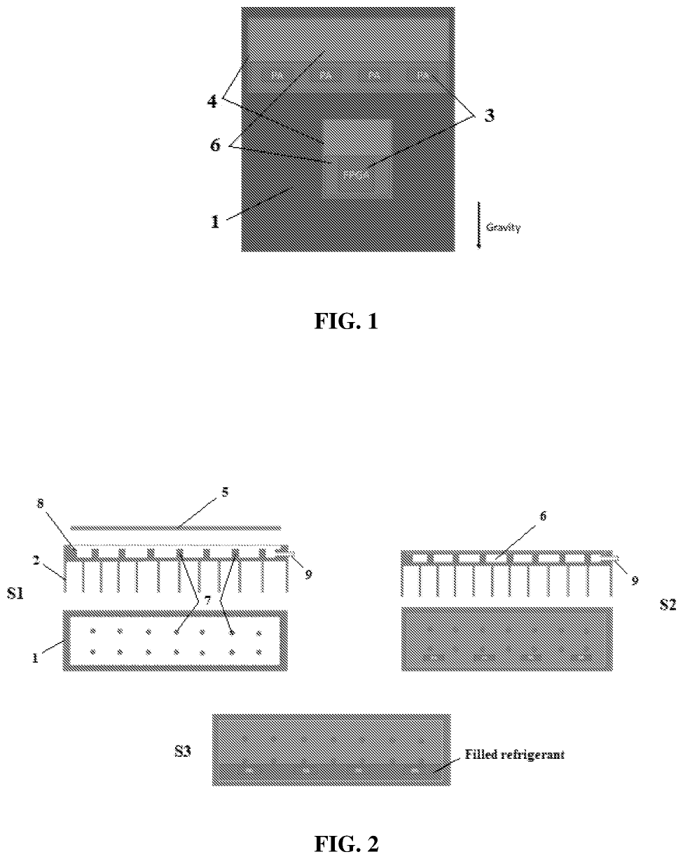

FIG. 1 is a view schematically illustrating a phase change heatsink according to an embodiment of the disclosure, and FIG. 2 illustrates steps for manufacturing the phase change heatsink according to the embodiment. The phase change heatsink according to this embodiment is mounted vertically along gravity direction, and includes a heatsink base 1 and many heatsink fins 2 (see FIG. 2). A plurality of heat sources 3 on a Printed Circuit Board (PCB), which is not shown, contact the heatsink base 1 at a side opposite to the heatsink fins 2. In this embodiment, the heat sources 3 include four Power Amplifiers (PAs) at the upper part of the heatsink base 1 and a Field Programmable Gate Array (FPGA) at the lower part of the heatsink base 1. It should be noted that the “lower part” herein does not mean the lower half of the heatsink base 1, and the “upper part” herein does not mean the upper half of the heatsink base 1. At positions corresponding to the PAs and the FPGA, two phase change heat spreaders 4 are integrated into the heatsink base 1.

Each phase change heat spreader 4 includes a cover 5 (see FIG. 2) attached to the heatsink base 1 at the side opposite to the heatsink fins 2. The cover 5 and the heatsink base 1 together define an enclosed cavity 6, which is partially filled with a certain amount of refrigerant. The refrigerant is filled to such a level that each of the PAs and the FPGA is covered by the refrigerant when the phase change heatsink is assembled with the PCB. A plurality of support pillars 7 (see FIG. 2) are provided in the enclosed cavity 6 to extend from the heatsink base 1 to the cover 5.

The phase change heatsink according to this embodiment is manufactured as follows.

Firstly, in step S1, the heatsink base 1 and the cover 5 are manufactured separately. The heatsink base 1 is die-casted from aluminum material to shape the cavity 6 as well as the support pillars 7 in the targeted phase change heat transfer area. Two or more cavities may be shaped in the die-casting step. In the die-casting step, a plurality of hentsink fins 2 are shaped integrally with the heatsink base 1 at an opposite side of the cavity 6. The cover 5 is also made of aluminum material.

Subsequently, in step S2, the cover 5 is attached to the heatsink base 1 to enclose the cavity 6. As can be seen from FIG. 2, the heatsink base 1 includes a stepped structure 8, and a periphery of the cover 5 bears against the stepped structure 8 before the attaching step is performed. To attach the cover 5, the periphery of the cover 5 is sealed to the heatsink base 1, and a central portion of the cover 5 is bonded to the support pillars 7 to keep the structure strength of the enclosed cavity 6. The sealing technology may be laser welding or friction stir welding to ensure reliable sealing. The bonding technology may be laser welding or glue bonding.

After the enclosed cavity 6 is shaped, in step S3, a certain amount of refrigerant is filled into the cavity 6 through a filling port 9. As shown in FIG. 2, the filling port 9 is formed at a side of the heatsink base 1. In other embodiments, however, the filling port 9 may be formed on a surface of the heatsink base 1 which is provided with the hentsink fins 2, or may be formed on the cover 5, according to actual needs. Finally, the filling port 9 is sealed to establish phase change heat spreader area in the heatsink base 1.

Accordingly, a phase change heatsink is obtained. In such a heatsink, the phase change heat spreader 4 is not made as a separate part, and is instead integrated into the heatsink base 1. When the heatsink is vertically mounted as shown in FIG. 1, the phase change heat spreader 4 which is partially filled with refrigerant naturally forms an evaporation area and a condensation area for the phase change heat transfer. The lower space filled with the refrigerant is the evaporation area, and the upper space without the refrigerant is the condensation area.

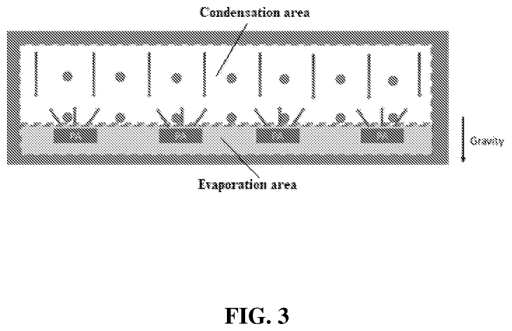

FIG. 3 is a schematic diagram illustrating a phase change heat transfer process inside the phase change heat spreader 4 for colling the PAs. When the heatsink is mounted vertically along the gravity direction, the filled refrigerant will sink at the bottom of the enclosed cavity 6 and will cover the PAs area. This naturally shapes the evaporation area and the condensation area inside the enclosed cavity 6. After the system is powered on, the PAs generate heat while working, and the heatsink base 1 contacting the PAs is heated. When the temperature of refrigerant is heated by hot PAs to reach the boiling point of the refrigerant, a boiling phenomenon will happen in the evaporation area of the enclosed cavity 6 and boiling vapor is generated. The boiling vapor will rise and diffuse to the whole condensation area, and release heat at the condensation area, which helps to spread the heat from the hot PAs to the whole phase change heat transfer area. The vapor will then be condensed into liquid because of lower temperature of the condensation area, and the condensed liquid will come back to the evaporation area by the effect of gravity.

With the above-mentioned phase change heatsink according to the embodiment of the disclosure, the phase change heat spreader 4 is directly integrated into the heatsink base 1. Thus, there is no extra thermal contact resistance compared with the traditional phase change heatsink in which a heat pipe or a vapor chamber is assembled with the heatsink base. Therefore, heat spreading on the heatsink base 1 and thereby the whole heatsink cooling efficiency is improved.

Since an internal phase change heat transfer loop is relied on gravity, there is no capillary structure needed inside the enclosed cavity 6, so the cavity 6 can be easily shaped when the heatsink is die-casted. Therefore, the proposed phase change structure is easier to be manufactured compared with traditional vapor chamber production process.

With the above-mentioned process for manufacturing the phase change heatsink according to the embodiment of the disclosure, laser welding and/or friction stir welding and/or glue bonding is/are employed to attach the cover to the heatsink base. Thus, it can overcome the problem that aluminum material used for die-casting heatsink can't be brazed. The phase change heat spreader with enclosed cavity shares the same aluminum material with the heatsink base, so it will not add extra weight to the heatsink. As compared with the traditional vapor chamber which has dimensional limitation from manufacturing view, the phase change heat spreader 4 in the embodiment of the disclosure can have a larger size.

The present disclosure also relates to a communication device comprising the above phase change heatsink and at least one heat source. As described above, the phase change heatsink is vertically mounted such that a lower portion of the phase change heat spreader 4 corresponds to the at least one heat source 3.

References in the present disclosure to “an embodiment”, “another embodiment” and so on, indicate that the embodiment described may include a particular feature, structure, or characteristic, but it is not necessary that every embodiment includes the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to implement such feature, structure, or characteristic in connection with other embodiments whether or not explicitly described.

It should be understood that, although the terms “first”, “second” and so on may be used herein to describe various elements, these elements should not be limited by these terms. These terms are only used to distinguish one element from another. For example, a first element could be termed a second element, and similarly, a second element could be termed a first element, without departing from the scope of the disclosure. As used herein, the term “and/or” includes any and all combinations of one or more of the associated listed terms.

The terminology used herein is for the purpose of describing particular embodiments only and is not intended to limit the present disclosure. As used herein, the singular forms “a”, “an” and “the” are intended to include the plural forms as well, unless the context clearly indicates otherwise. It will be further understood that the terms “comprises”, “comprising”, “has”, “having”, “includes” and/or “including”, when used herein, specify the presence of stated features, elements, and/or components, but do not preclude the presence or addition of one or more other features, elements, components and/or combinations thereof. The terms “connect”, “connects”, “connecting” and/or “connected” used herein cover the direct and/or indirect connection between two elements.

The present disclosure includes any novel feature or combination of features disclosed herein either explicitly or any generalization thereof. Various modifications and adaptations to the foregoing exemplary embodiments of this disclosure may become apparent to those skilled in the relevant arts in view of the foregoing description, when read in conjunction with the accompanying drawings. However, any and all modifications will still fall within the scope of the non-Limiting and exemplary embodiments of this disclosure.

1. A phase change heatsink, comprising a heatsink base and a phase change heat spreader integrated into the heatsink base, wherein the phase change heat spreader includes a cover attached to the heatsink base and defines an enclosed cavity, one or more support pillars are provided in the enclosed cavity to extend from the heatsink base to the cover, and the enclosed cavity is partially filled with refrigerant.

2. A process for manufacturing a phase change heatsink according to claim 1, comprising steps of:
a) die-casting the heatsink base to shape the cavity and the support pillars;
b) attaching the cover to the heatsink base to enclose the cavity; and
c) filling a certain amount of refrigerant into the cavity through a filling port, and sealing the filling port,
wherein the attaching step b) further comprises a step b1) of sealing a periphery of the cover to the heatsink base, and a step b2) of bonding a central portion of the cover to the support pillars.

3. The process according to claim 2, wherein the sealing step b1) is performed by laser welding or friction stir welding.

4. The process according to claim 2, wherein the bonding step b2) is performed by laser welding or glue bonding.

5. The process according to claim 2, wherein the heatsink base and the cover are each made of aluminum material.

6. The process according to claim 2, wherein the filling port is formed at a side of the heatsink base.

7. The process according to claim 2, wherein two or more cavities are shaped in the die-casting step a).

8. The process according to claim 2, wherein in the die-casting step a), a plurality of heatsink fins are shaped integrally with the heatsink base at an opposite side of the cavity.

9. The process according to claim 2, wherein the heatsink base includes a stepped structure against which the periphery of the cover bears before the attaching step b) is performed.

10. A communication device, comprising at least one heat source and a phase change heatsink according to claim 1, wherein the phase change heatsink is vertically mounted such that a lower portion of the phase change heat spreader corresponds to the at least one heat source.
